(19) United States
(12) Patent Application Publication
(10) Pub. No.: US 2025/0040115 A1
(43) Pub. Date: Jan. 30, 2025

(54) NANOSHEET SRAM WITH TAPERED REGION

(71) Applicant: INTERNATIONAL BUSINESS MACHINES CORPORATION, ARMONK, NY (US)

(72) Inventors: Min Gyu Sung, Latham, NY (US); Ruilong Xie, Niskayuna, NY (US); Julien Frougier, Albany, NY (US)

(21) Appl. No.: 18/358,981

(22) Filed: Jul. 26, 2023

(51) Int. Cl. H10B 10/00; H01L 29/06; H01L 29/417; H01L 29/423; H01L 29/775; H01L 29/786

(52) U.S. Cl. CPC H10B 10/125; H01L 29/0673; H01L 29/41733; H01L 29/42392; H01L 29/775; H01L 29/78696

(57) ABSTRACT

Embodiments of present invention provide a static random-access-memory (SRAM). The SRAM includes a first and a second pull-down (PD) transistor having respectively a first and a fourth set of nanosheets of a first width; a first and a second pass-gate (PG) transistor having respectively a second and a fifth set of nanosheets of a second width; and a first and a second pull-up (PU) transistor having respectively a third and a sixth set of nanosheets of a third width, wherein the first width is wider than the second width, the second width is wider than the third width, the first set of nanosheets is substantially aligned with the second set of nanosheets at one side of the first and second sets of nanosheets, and the fourth set of nanosheets is substantially aligned with the fifth set of nanosheets at one side of the fourth and fifth sets of nanosheets.

### BACKGROUND

The present application relates to manufacturing of semiconductor integrated circuits. More particularly, it relates to schematic layout of a nanosheet transistor based static random-access-memory device.

Static random-access memory (SRAM) is a type of memory device that is commonly used to store digital information in semiconductor integrated circuits. A SRAM device usually includes two pull-down (PD) transistors, two pull-up (PU) transistors, and two pass-gate (PG) transistors that are uniquely interconnected. To increase reading and/or writing margins, it is generally preferred that, among the three types of transistors, the PD transistors have the strongest current, the PU transistors have the weakest current, and the PG transistors have a medium current whose strength is between the PD transistors and the PU transistors. In a fin-FET based SRAM, this is achieved by using different number of fins for each type of transistors. However, a solution has yet to be found for nanosheet transistor based SRAM.

### SUMMARY

Embodiments of present invention provide a static random-access-memory (SRAM). The SRAM includes a first pull-down (PD) transistor based on a first set of nanosheets having a first width; a first pass-gate (PG) transistor based on a second set of nanosheets having a second width; and a first pull-up (PU) transistor based on a third set of nanosheets having a third width, where the first width of the first set of nanosheets is wider than the second width of the second set of nanosheets, and the second width of the second set of nanosheets is wider than the third width of the third set of nanosheets, and where a first side of the first set of nanosheets is substantially aligned with a first side of the second set of nanosheets.

In one embodiment, the first set of nanosheets has a second side that is parallel to the first side of the first set of nanosheets, and the third set of nanosheets is at the second side of the first set of nanosheets.

According to one embodiment, the SRAM further includes a source/drain contact of the first PD transistor at a frontside of the SRAM, and a source/drain contact of the first PU transistor at a backside of the SRAM.

In one embodiment, the source/drain contact of the first PD transistor is aligned with the source/drain contact of the first PU transistor in a direction perpendicular to the first and the second side of the first set of nanosheets.

According to another embodiment, the SRAM further includes a second PD transistor based on a fourth set of nanosheets having the first width; a second PG transistor based on a fifth set of nanosheets having the second width; and a second PU transistor based on a sixth set of nanosheets having the third width, where the second set of nanosheets is separated from the third set of nanosheets by a first distance D1, the third set of nanosheets is separated from the sixth set of nanosheets by a second distance D2, and the sixth set of nanosheets is separated from the fifth set of nanosheets by a third distance D3, and D1, D2, and D3 are substantially same.

In one embodiment, the first set of nanosheets and the second set of nanosheets are formed by patterning a raw set of nanosheets with a tapered region between the first set of nanosheets and the second set of nanosheets.

In another embodiment, the tapered region is replaced with a source/drain region shared by the first PD transistor and the first PG transistor.

In yet another embodiment, the first set of nanosheets and the third set of nanosheets share a same gate metal.

According to one embodiment, the first PD transistor is capable of producing a first current, the first PG transistor is capable of producing a second current, and the first PU transistor is capable of producing a third current, wherein the first current is larger than the second current, and the second current is larger than the third current.

### BRIEF DESCRIPTION OF THE DRAWINGS

The present invention will be understood and appreciated more fully from the following detailed description of embodiments of present invention, taken in conjunction with accompanying drawings of which:

FIG. 1 is a demonstrative illustration of a schematic layout of a nanosheet transistor based SRAM device according to one embodiment of present invention;

FIG. 2 is a demonstrative illustration of a schematic layout of a nanosheet transistor based SRAM device according to another embodiment of present invention; and

FIG. 3 is a demonstrative illustration of cross-sectional views of the nanosheet transistor based SRAM device as illustrated in FIG. 2 according to one embodiment of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

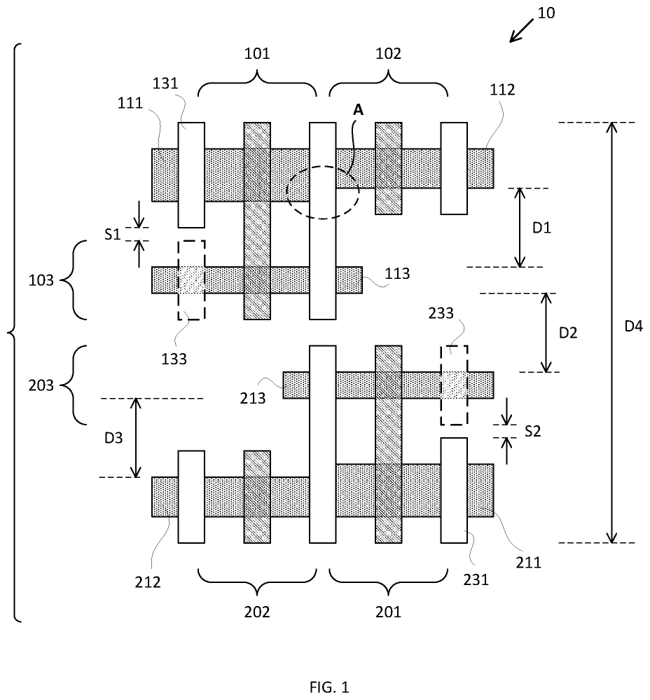

FIG. 1 is a demonstrative illustration of a schematic layout of a nanosheet transistor based SRAM device according to one embodiment of present invention. More particularly, embodiments of present invention provide a SRAM device 10 that includes six nanosheet transistors. The six nanosheet transistors include a first and a second PD transistor 101 and 201 having respectively a first and a fourth set of nanosheets 111 and 211; a first and a second PG transistor 102 and 202 having respectively a second and a fifth set of nanosheets 112 and 212; and a first and a second PU transistor 103 and 203 having respectively a third and a sixth set of nanosheets 113 and 213.

As is illustrated in FIG. 1, the second set of nanosheets 112 of the first PG transistor 102 is separated from the third set of nanosheets 113 of the first PU transistor 103 by a distance D1; the third set of nanosheets 113 of the first PU transistor 103 is separated from the sixth set of nanosheets 213 of the second PU transistor 203 by a distance D2; and the sixth set of nanosheets 213 of the second PU transistor 203 is separated from the fifth set of nanosheets 212 of the second PG transistor 202 by a distance D3. Here, distances D1, D2, and D3 are defined as distances measured from adjacent edges or sides of the respective sets of nanosheets. In order to reduce footprint of the SRAM device 10 such as reducing the overall device height D4 to meet the increasing demand for device scaling, in one embodiment distances D1, D2, and D3 may be made minimal, to the extent practically possible. In another embodiment, distances D1, D2, and D3 may be made equal as well for balanced device performance. In other words, D1, D2, and D3 may be substantially the same.

According to one embodiment, the third set of nanosheets 113 is formed or placed between the first set of nanosheets 111 and the fifth set of nanosheets 212 and the sixth set of nanosheets is formed or placed between the second set of nanosheets 112 and the fourth set of nanosheets 211. In other words, the third set of nanosheets 113 is at the lower side or lower edge of the first set of nanosheets 111 and the sixth set of nanosheets 213 is at the upper side or upper edge of the fourth set of nanosheets 211 as is illustrated in FIG. 1. In one embodiment, the lower side or lower edge of the first set of nanosheets 111 is made generally and substantially parallel to the upper side or upper edge of the first set of nanosheets 111.

In order to increase the current of the first and the second PD transistors 101 and 201 such that they have bigger current than that of the first and the second PG transistors 102 and 202 for device performance enhancement, embodiments of present invention provide having the first and the fourth set of nanosheets 111 and 211 of the first and the second PD transistor 101 and 201 wider than the second and the fifth set of nanosheets 112 and 212 of the first and the second PG transistor 102 and 202. More particularly, one embodiment of present invention provide having the width of the first set of nanosheets 111 extend, from the width of the second set of nanosheets 112, downwardly towards the third set of nanosheets 113 and having the width of the fourth set of nanosheets 211 extend, from the width of the fifth set of nanosheets 212, upwardly towards the sixth set of nanosheets 213 such that the SRAM device 10 may be able to maintain the same device height D4.

The downwardly extending of the width of the first set of nanosheets 111 may reduce the spacing between the lower edge or lower side of the first set of nanosheets 111 and the upper edge or upper side of the third set of nanosheets 113 to be less than the distance D1. In order to accommodate forming source/drain contacts, which may be trench contacts, of the first PD transistor 101 and the first PU transistor 103 with the reduced spacing between them, embodiments of present invention provide having a source/drain contact 131 of the first PD transistor 101 formed at a frontside (or backside) of the device wafer or the SRAM device 10 and a source/drain contact 133 of the first PU transistor 103 formed at a backside (or frontside) of the device wafer or the SRAM device 10, thereby avoiding the tight spacing S1 between the source/drain contacts 131 and 133 should the source/drain contacts 131 and 133 be both formed at a same side, either frontside or backside, of the device wafer or the SRAM. The device wafer is a semiconductor wafer upon which the SRAM device 10 is formed. In one embodiment, the source/drain contact 131 of the first PD transistor 101 and the source/drain contact 133 of the first PU transistor 103 may be aligned in a direction perpendicular to a first and a second sides or edges of the first set of nanosheets 111, perpendicular to a first and a second sides or edges of the third set of nanosheets 113, and/or perpendicular to a longitudinal direction of the first set of nanosheets 111 or a longitudinal direction of the third s.

Similarly, the upwardly extending of the width of the fourth set of nanosheets 211 may reduce the spacing between the upper edge or upper side of the fourth set of nanosheets 211 and the lower edge or lower side of the sixth set of nanosheets 213 to be less than the distance D3. Embodiments of present invention provide having a source/drain contact 231 of the second PD transistor 201 formed at a frontside (or backside) of the device wafer or the SRAM device 10 and a source/drain contact 233 of the second PU transistor 203 formed at a backside (or frontside) of the device wafer or the SRAM device 10, thereby avoiding the tight spacing S2 between the source/drain contacts 231 and 233 should the source/drain contacts 231 and 233 be both formed at a same side, either frontside or backside, of the device wafer or the SRAM device 10. In one embodiment, the source/drain contact 231 of the second PD transistor 201 and the source/drain contact 233 of the second PU transistor 203 may be aligned in a direction perpendicular to a first and a second sides or edges of the fourth set of nanosheets 211, and perpendicular to a first and a second sides of edges of the sixth set of nanosheets 213.

The downwardly extending of the width of the first set of nanosheets 111 may result in a tapered region between the first set of nanosheets 111 and the second set of nanosheets 112, as indicated in FIG. 1 by a dashed circle A. In one embodiment, the tapered region may be in an area such that the tapered region may be replaced later by a source/drain region shared by the first PD transistor 101 and the first PG transistor 102. For example, during the manufacturing process of the SRAM device 10, a raw set of nanosheets may be patterned in lithographic patterning step to form the first set of nanosheets 111 and the second set of nanosheets 112 with a tapered region in between the first and the second set of nanosheets 111 and 112. The tapered region may be further recessed or selectively etched away later to create an opening and replaced by source/drain regions of the first PD transistor 101 and the first PG transistor 102. By downwardly extending the width of the first set of nanosheets 111, as is illustrated in FIG. 1, an upper edge or upper side of the first set of nanosheets 111 of the first PD transistor 101 is and/or remains substantially aligned with an upper edge or upper side of the second set of nanosheets 112 of the first PG transistor 102.

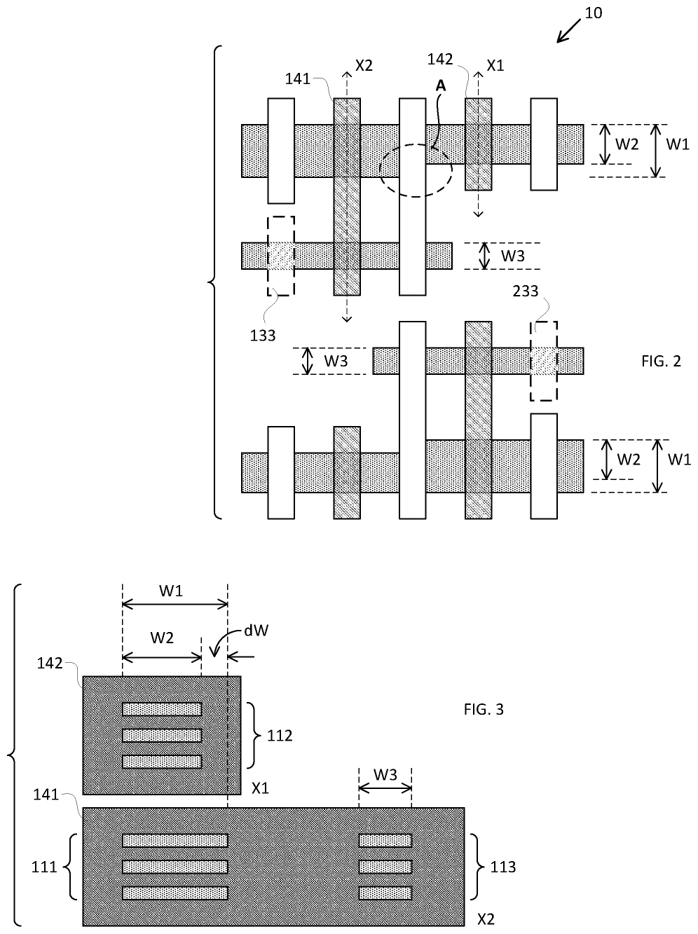

FIG. 2 is a demonstrative illustration of a schematic layout of a nanosheet transistor based SRAM device according to another embodiment of present invention. More specifically, FIG. 2 illustrates the SRAM device 10 as is illustrated in FIG. 1, and the first set of nanosheets 111 of the first PD transistor 101 has a first width W1; the second set of nanosheets 112 of the first PG transistor 102 has a second width W2; and the third set of nanosheets 113 of the first PU transistor 103 has a third width W3. In particular, the first width W1 of the first PD transistor 101 is wider than the second width W2 of the first PG transistor 102, and the second width W2 of the first PG transistor 102 is wider than the third width W3 of the first PU transistor 103. As a result, embodiments of present invention enable, among the three transistors, the first PD transistor 101 to have a strongest current, the first PU transistor 103 to have the weakest current, and the first PG transistor 102 to have a medium current that is between that of the first PD transistor 101 and that of the first PU transistor 103. In other words, the first PD transistor 101 may be able to produce a current that is larger than a current produced by the first PG transistor 102 and the first PG transistor 102 may be able to produce a current that is larger than a current produced by the first PU transistor 103.

Similarly, the fourth set of nanosheets 211 of the second PD transistor 201 has the first width W1; the fifth set of nanosheets 212 of the second PG transistor 202 has the second width W2; and the sixth set of nanosheets 213 of the second PU transistor 203 has the third width W3. The first width W1 of the second PD transistor 201 is wider than the second width W2 of the second PG transistor 202, and the second width W2 of the second PG transistor 202 is wider than the third width W3 of the second PU transistor 203. The second PD transistor 201 may be able to produce a current that is larger than a current produced by the second PG transistor 202 and the second PG transistor 202 may be able to produce a current that is larger than a current produced by the second PU transistor 203. FIG. 2 also illustrates a first dashed line X1 and a second dashed line X2 to indicate cross-section areas whose details are described below in details with reference to FIG. 3.

FIG. 3 is a demonstrative illustration of cross-sectional views of the nanosheet transistor based SRAM device as illustrated in FIG. 2 according to one embodiment of present invention. More particularly, the first set of nanosheets 111 and the third set of nanosheets 113 are surrounded by a gate metal 141, with the first set of nanosheets 111 having the first width W1 and the third set of nanosheets 113 having the third width W3. In other words, the first set of nanosheets 111 and the third set of nanosheets 113 share a gate metal 141. The second set of nanosheets 112 is surrounded by a gate metal 142 and has the second width W2. The first set of nanosheets 111 and the second set of nanosheets 112 are substantially aligned at their respective first sides or left sides or left edges as is illustrated in FIG. 3, or at their respective upper edges as is illustrated in FIG. 2. In the meantime, the first set of nanosheets 111 has an extended width, from the second width W2 of the second set of nanosheets 112, towards the third set of nanosheets 113. The first width W1 is wider than the second width W2 by a difference dW.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A static random-access-memory (SRAM) comprising:
a first pull-down (PD) transistor based on a first set of nanosheets having a first width;
a first pass-gate (PG) transistor based on a second set of nanosheets having a second width; and
a first pull-up (PU) transistor based on a third set of nanosheets having a third width,
wherein the first width of the first set of nanosheets is wider than the second width of the second set of nanosheets, and the second width of the second set of nanosheets is wider than the third width of the third set of nanosheets, and wherein a first side of the first set of nanosheets is substantially aligned with a first side of the second set of nanosheets.

2. The SRAM of claim 1, wherein the first set of nanosheets has a second side that is parallel to the first side of the first set of nanosheets, and the third set of nanosheets is at the second side of the first set of nanosheets.

3. The SRAM of claim 2, further comprising a source/drain contact of the first PD transistor at a frontside of the SRAM, and a source/drain contact of the first PU transistor at a backside of the SRAM.

4. The SRAM of claim 3, wherein the source/drain contact of the first PD transistor is aligned with the source/drain contact of the first PU transistor in a direction perpendicular to the first and the second side of the first set of nanosheets.

5. The SRAM of claim 1, further comprising:
a second PD transistor based on a fourth set of nanosheets having the first width;
a second PG transistor based on a fifth set of nanosheets having the second width; and
a second PU transistor based on a sixth set of nanosheets having the third width,
wherein the second set of nanosheets is separated from the third set of nanosheets by a first distance D1, the third set of nanosheets is separated from the sixth set of nanosheets by a second distance D2, and the sixth set of nanosheets is separated from the fifth set of nanosheets by a third distance D3, and wherein D1, D2, and D3 are substantially same.

6. The SRAM of claim 5, wherein the first set of nanosheets and the second set of nanosheets are formed by patterning a raw set of nanosheets with a tapered region between the first set of nanosheets and the second set of nanosheets.

7. The SRAM of claim 6, wherein the tapered region is replaced with a source/drain region shared by the first PD transistor and the first PG transistor.

8. The SRAM of claim 5, wherein the first set of nanosheets and the third set of nanosheets share a same gate metal.

9. The SRAM of claim 1, wherein the first PD transistor is capable of producing a first current, the first PG transistor is capable of producing a second current, and the first PU transistor is capable of producing a third current, wherein the first current is larger than the second current, and the second current is larger than the third current.

10. A static random-access-memory (SRAM) comprising:
a first and a second pull-down (PD) transistor based on a first and a fourth set of nanosheets, the first and the fourth set of nanosheets having a first width;
a first and a second pass-gate (PG) transistor based on a second and a fifth set of nanosheets, the second and the fifth set of nanosheets having a second width; and
a first and a second pull-up (PU) transistor based on a third and a sixth set of nanosheets, the third and the sixth set of nanosheets having a third width,
wherein the first width of the first and the fourth set of nanosheets is wider than the second width of the second and the fifth set of nanosheets, and the second width of the second and the fifth set of nanosheets is wider than the third width of the third and the sixth set of nanosheets, and wherein a first side of the first set of nanosheets is substantially aligned with a first side of the second set of nanosheets, and a first side of the fourth set of nanosheets is substantially aligned with a first side of the fifth set of nanosheets.

11. The SRAM of claim 10, wherein the third set of nanosheets is between the first set of nanosheets and the fifth set of nanosheets, and the sixth set of nanosheets is between the second set of nanosheets and the fourth set of nanosheets.

12. The SRAM of claim 11, further comprising a source/drain contact of the first PD transistor and the second PD transistor formed at a frontside of the SRAM, and a source/drain contact of the first PU transistor and the second PU transistor formed at a backside of the SRAM.

13. The SRAM of claim 12, wherein the source/drain contact of the first PD transistor is aligned with the source/drain contact of the first PU transistor in a direction perpendicular to a longitudinal direction of the first and the third set of nanosheets.

14. The SRAM of claim 10, wherein the second set of nanosheets is separated from the third set of nanosheets by a first distance D1, the third set of nanosheets is separated from the sixth set of nanosheets by a second distance D2, and the sixth set of nanosheets is separated from the fifth set of nanosheets by a third distance D3, and wherein D1, D2, and D3 are substantially equal.

15. The SRAM of claim 14, wherein the first set of nanosheets is separated from the third set of nanosheets by a distance less than the first distance D1, and the fourth set of nanosheets is separated from the sixth set of nanosheets by a distance less than the third distance D3.

16. The SRAM of claim 10, wherein the first and the second PD transistor are capable of producing a first current, the first and the second PG transistor are capable of producing a second current, and the first and the second PU transistor are capable of producing a third current, wherein the first current is larger than the second current, and the second current is larger than the third current.

17. A static random-access-memory (SRAM) comprising:
a first and a second pull-down (PD) transistor having respectively a first and a fourth set of nanosheets of a first width;
a first and a second pass-gate (PG) transistor having respectively a second and a fifth set of nanosheets of a second width; and
a first and a second pull-up (PU) transistor having respectively a third and a sixth set of nanosheets of a third width,
wherein the first width is wider than the second width, and the second width is wider than the third width, and the first set of nanosheets is substantially aligned with the second set of nanosheets at one side of the first and the second set of nanosheets, and the fourth set of nanosheets is substantially aligned with the fifth set of nanosheets at one side of the fourth and the fifth set of nanosheets.

18. The SRAM of claim 17, further comprising a source/drain contact of the first PD transistor and the second PD transistor formed at a frontside of the SRAM, and a source/drain contact of the first PU transistor and the second PU transistor formed at a backside of the SRAM.

19. The SRAM of claim 18, wherein the source/drain contact of the first PD transistor is aligned with the source/drain contact of the first PU transistor in a direction perpendicular to a longitudinal direction of the first and the third set of nanosheets, wherein the source/drain contacts of the first PD transistor and the first PU transistor are trench contacts.

20. The SRAM of claim 17, wherein the second set of nanosheets is separated from the third set of nanosheets by a first distance D1, the third set of nanosheets is separated from the sixth set of nanosheets by a second distance D2, and the sixth set of nanosheets is separated from the fifth set of nanosheets by a third distance D3, and wherein D1 equals D2 and equals D3.
